(19) United States
(12) Patent Application Publication
(10) Pub. No.: US 2020/0144237 A1
(43) Pub. Date: May 7, 2020

(54) SEMICONDUCTOR PACKAGE

(71) Applicant: SAMSUNG ELECTRONICS CO., LTD., Suwon-si (KR)

(72) Inventors: Seungon Kang, Suwon-si (KR); Han Kim, Suwon-si (KR)

(73) Assignee: SAMSUNG ELECTRONICS CO., LTD., Suwon-si (KR)

(21) Appl. No.: 16/654,764

(22) Filed: Oct. 16, 2019

(30) Foreign Application Priority Data
Nov. 5, 2018 (KR) 10-2018-0134270

(51) Int. Cl. H01L 25/16; H01L 23/13; H01L 35/10; H01L 23/31; H01L 23/538; H01L 35/08; H01L 35/32; H01L 23/00; H01L 23/38

(52) U.S. Cl. CPC H01L 25/16; H01L 2224/24265; H01L 35/10; H01L 23/3128; H01L 23/5386; H01L 23/5384; H01L 35/08; H01L 35/325; H01L 24/32; H01L 24/48; H01L 23/38; H01L 24/24; H01L 2924/19102; H01L 2224/48091; H01L 2224/48106; H01L 2224/32145; H01L 24/73; H01L 2224/73215; H01L 2224/32225; H01L 2224/48227; H01L 2224/73265; H01L 24/33; H01L 2224/33181; H01L 2224/73267; H01L 23/13

(57) ABSTRACT

A semiconductor package includes a frame having a through-hole, a semiconductor chip disposed in the through-hole of the frame, and having an active surface on which a connection pad is disposed and an inactive surface opposite to the active surface, a thermoelectric device disposed on the inactive surface of the semiconductor chip, in the through-hole of the frame, and including a semiconductor layer and an electrode layer connected to the semiconductor layer, an encapsulant sealing at least portions of the semiconductor chip and the thermoelectric device, and a first connection structure disposed on the active surface of the semiconductor chip, and including a first redistribution layer electrically connected to the connection pad of the semiconductor chip.

### CROSS-REFERENCE TO RELATED APPLICATION(S)

This application claims the benefit of priority to Korean Patent Application No. 10-2018-0134270 filed on Nov. 5, 2018 in the Korean Intellectual Property Office, the entire disclosure of which is incorporated herein by reference.

### TECHNICAL FIELD

The present disclosure relates to a semiconductor package.

### BACKGROUND

Semiconductor packages are continuously pursuing lightness, thinness, shortness, and small shapes in terms of design, and pursuing a System in Package (SiP) package which requires complexity and versatility in terms of functionality. One type of package technology suggested to satisfy the technical demand described above, is a fan-out semiconductor package. Such a fan-out semiconductor package has a compact size and may allow a plurality of pins to be implemented by redistributing connection terminals outwardly of a region in which a semiconductor chip is disposed.

In particular, in a recently developed semiconductor package having a package on package (POP) structure, a structure, capable of improving heat dissipation characteristics while significantly reducing a thickness of a package, is required. In addition, in the case of an application processor (AP) chip in a semiconductor package mounted on a mobile product, concentrated heat is generated in a CPU core, so that a structure for removing heat from a position close to a heat generating point in a short period of time is required.

### SUMMARY

According to an aspect of the present disclosure, a semiconductor package provides improved heat dissipation characteristics.

According to an aspect of the present disclosure, in a semiconductor package, a thermoelectric device is disposed on an inactive surface of a semiconductor chip.

The semiconductor package may include: a frame having a through-hole; a semiconductor chip disposed in the through-hole of the frame, and having an active surface on which a connection pad is disposed and an inactive surface opposite to the active surface; a thermoelectric device disposed on the inactive surface of the semiconductor chip, in the through-hole of the frame, and including a semiconductor layer and an electrode layer connected to the semiconductor layer; an encapsulant sealing at least portions of the semiconductor chip and the thermoelectric device; and a first connection structure disposed on the active surface of the semiconductor chip, and including a first redistribution layer electrically connected to the connection pad of the semiconductor chip.

According to another aspect of the present disclosure, a semiconductor package may include a first semiconductor package including a frame having a through-hole, a first semiconductor chip disposed in the through-hole of the frame and having an active surface on which a connection pad is disposed and an inactive surface disposed opposite to the active surface; a thermoelectric device disposed on the inactive surface of the first semiconductor chip in the through-hole of the frame; a first encapsulant sealing at least a portion of the first semiconductor chip; a first connection structure including a first redistribution layer disposed on the active surface of the first semiconductor chip and electrically connected to the connection pad of the first semiconductor chip; and a second connection structure disposed on the frame and including a second redistribution layer electrically connected to the connection pad of the first semiconductor chip. The semiconductor package may further include a second semiconductor package disposed on the first semiconductor package, and including a wiring substrate electrically connected to the second connection structure through a connection terminal, at least one second semiconductor chip disposed on the wiring substrate, and a second encapsulant sealing at least a portion of the second semiconductor chip.

Other features and aspects will be apparent from the following detailed description, the drawings, and the claims.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is a schematic cross-sectional view illustrating a packaging process of a fan-in semiconductor package;

FIG. 5 is a schematic cross-sectional view illustrating a case in which a fan-in semiconductor package is mounted on an interposer substrate and is ultimately mounted on a mainboard of an electronic device;

FIG. 6 is a schematic cross-sectional view illustrating a case in which a fan-in semiconductor package is embedded in an interposer substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a semiconductor package;

FIG. 10 is a schematic plan view taken along line I-I′ of the semiconductor package of FIG. 9;

FIG. 11 is a schematic cross-sectional view illustrating another example of a semiconductor package.

FIG. 12 is a schematic cross-sectional view illustrating another example of a semiconductor package;

FIG. 13 is a schematic cross-sectional view illustrating another example of a semiconductor package;

FIG. 14 is a schematic cross-sectional view illustrating another example of a fan-out semiconductor package; and

FIG. 15 is a schematic plan view illustrating an effect in a case in which the semiconductor package according to the disclosure is applied to an electronic device.

### DETAILED DESCRIPTION

Hereinafter, embodiments of the present disclosure will be described as follows with reference to the attached drawings.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present disclosure will be described with reference to schematic views illustrating embodiments of the present disclosure. In the drawings, for example, due to manufacturing techniques and/or tolerances, modifications of the shape shown may be estimated. Thus, embodiments of the present disclosure should not be construed as being limited to the particular shapes of regions shown herein, for example, to include a change in shape results in manufacturing. The following embodiments may also be constituted by one or a combination thereof.

The contents of the present disclosure described below may have a variety of configurations and propose only a required configuration herein, but are not limited thereto.

Electronic Device

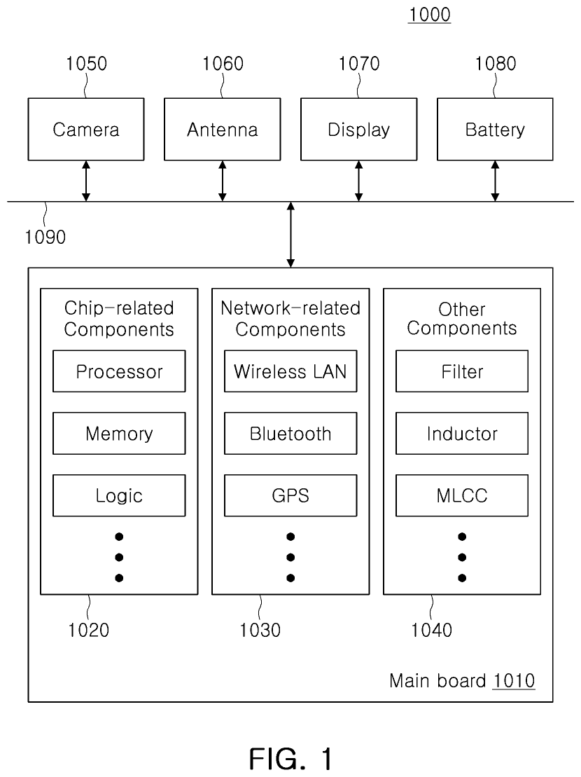

FIG. 1 is a schematic block diagram illustrating an example of an electronic device system.

Referring to FIG. 1, an electronic device 1000 may accommodate a mainboard 1010 therein. The mother board 1010 may include chip related components 1020, network related components 1030, other components 1040, or the like, physically or electrically connected thereto. These components may be connected to others to be described below to form various signal lines 1090.

The chip associated components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like, or the like. However, the chip associated components 1020 are not limited thereto, and may include other types of chip associated components. In addition, the chip-associated components 1020 may be combined with each other.

The network associated components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the abovementioned protocols. However, the network associated components 1030 are not limited thereto, but may also include a variety of other wireless or wired standards or protocols. In addition, the network associated components 1030 may be combined with each other, together with the chip associated components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 includes other components that may or may not be physically or electrically connected to the mainboard 1010. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device able to process data.

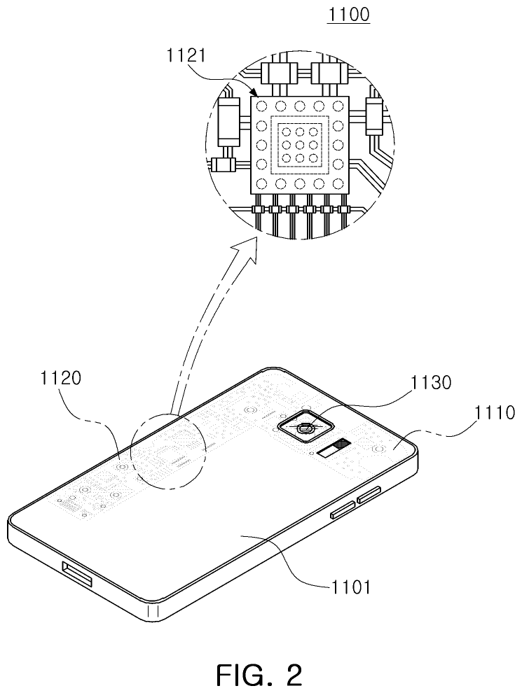

FIG. 2 is a schematic perspective view illustrating an example of an electronic device.

Referring to FIG. 2, a semiconductor package may be used for various purposes in the various electronic devices 1000 as described above. For example, a printed circuit board 1110 may be accommodated in a body 1101 of a smartphone 1100, and various electronic components 1120 may be physically or electrically connected to the printed circuit board 1110. In addition, other components that may or may not be physically or electrically connected to the printed circuit board 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

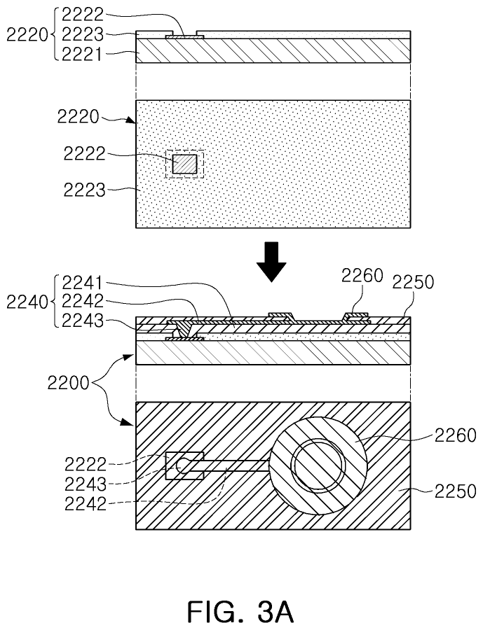

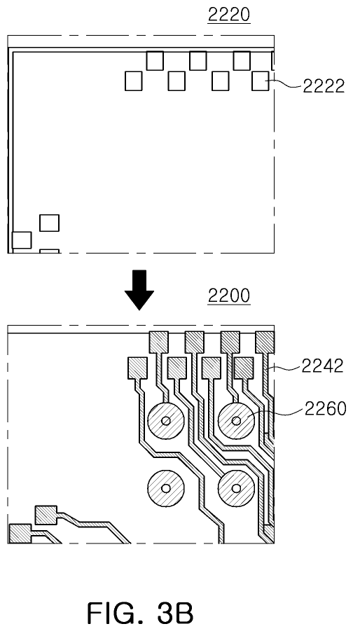

FIGS. 3A and 3B are schematic cross-sectional views illustrating states of a fan-in semiconductor package before and after being packaged.

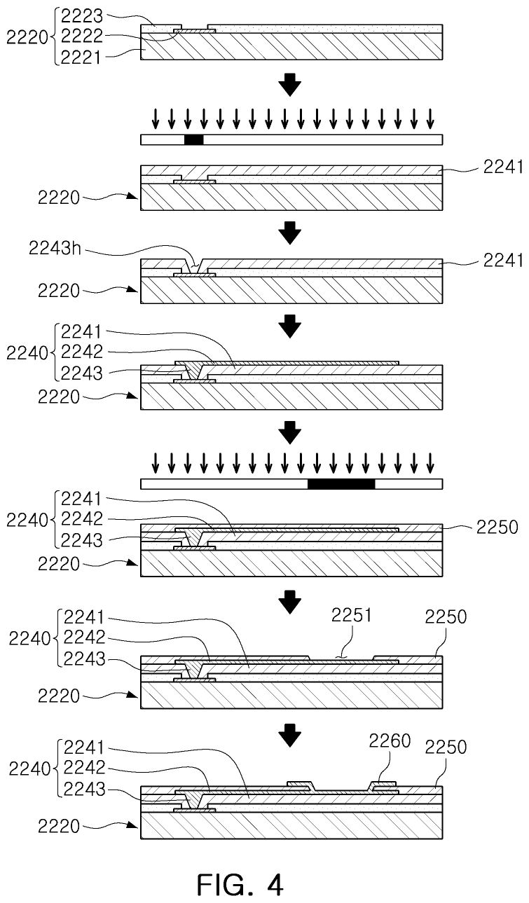

FIG. 4 is schematic cross-sectional views illustrating a packaging process of a fan-in semiconductor package.

Referring to FIGS. 3A, 3B, and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimageable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. Here, even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

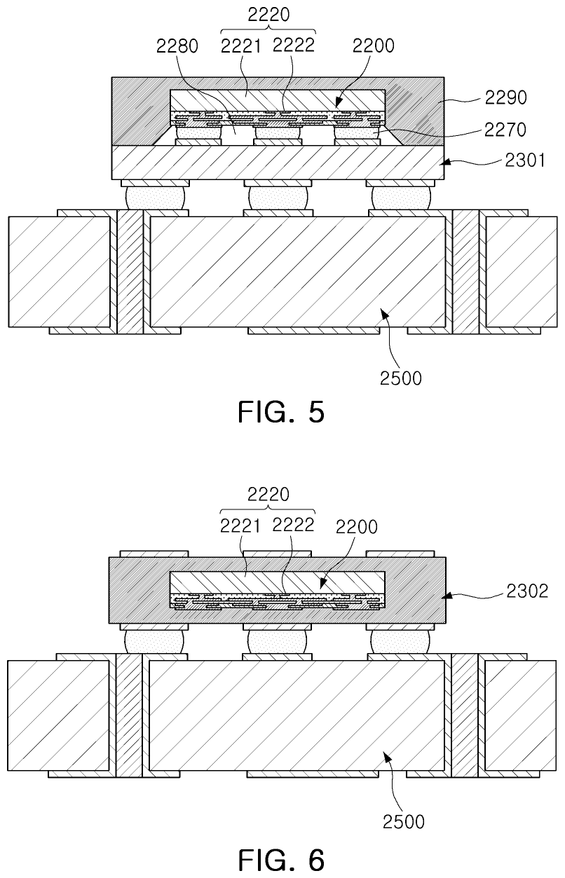

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may ultimately be mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

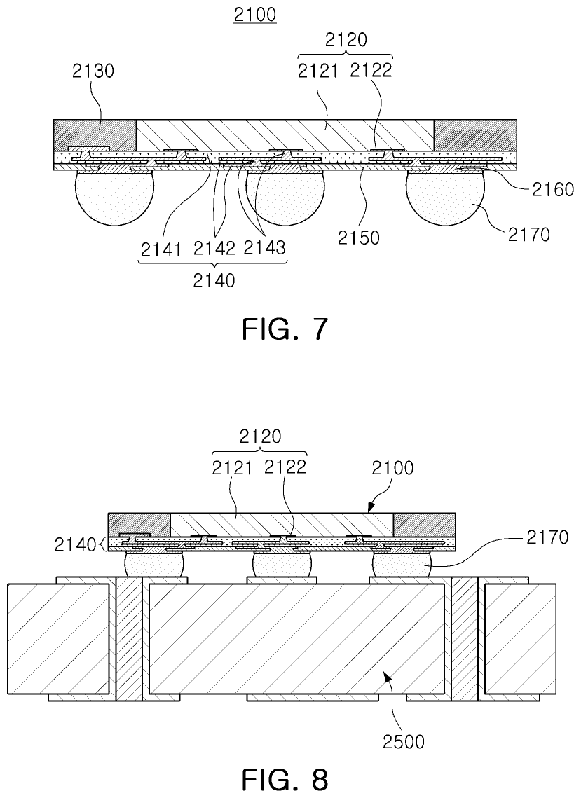

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

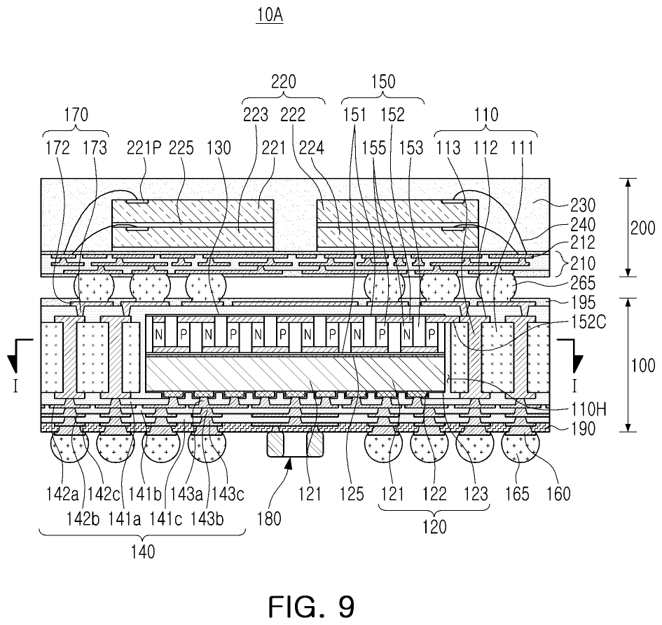

FIG. 9 is a schematic cross-sectional view illustrating an example of a semiconductor package.

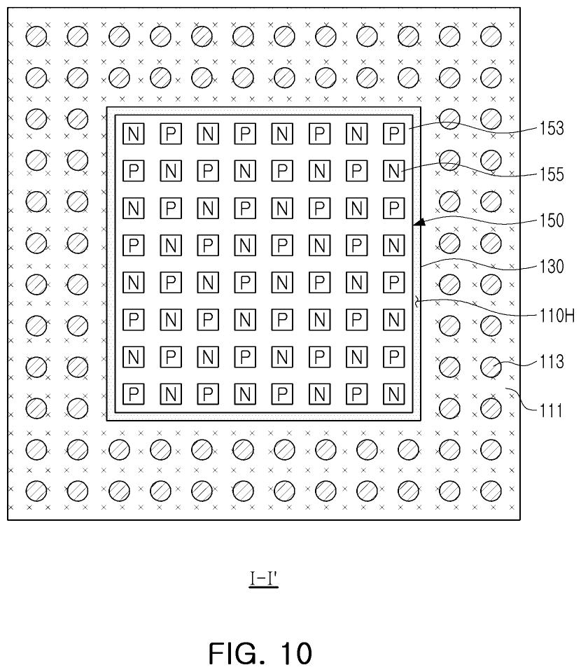

FIG. 10 is a schematic plan view taken along line I-I′ of the semiconductor package of FIG. 9.

Referring to FIGS. 9 and 10, a semiconductor package 10A according to an example embodiment is a package-on-package (POP) structure, including a first semiconductor package 100 and a second semiconductor package 200, vertically stacked, and the second semiconductor package 200 is stacked on the first semiconductor package 100. The first semiconductor package 100 may include a frame 110 having a through-hole 110H, a first semiconductor chip 120 disposed in the through-hole 110H of the frame 110 and having an active surface on which the connection pad 122 is disposed and an inactive surface disposed opposite to the active surface, a thermoelectric device 150 disposed on the inactive surface of the first semiconductor chip 120, a first encapsulant 130 sealing at least portions of the frame 110 and the first semiconductor chip 120, a first connection structure 140 disposed on the frame 110 and the active surface of the first semiconductor chip 120 and including the first redistribution layers 142a, 142b, and 142c, a second connection structure 170 disposed on the first encapsulant 130 and including an upper redistribution layer 172, a first passivation layer 190 disposed on the first connection structure 140, an underbump metal layer 160 disposed in an opening of the first passivation layer 190, an electrical connection metal 165 disposed on the first passivation layer 190 and connected to the underbump metal layer 160, and a passive component 180 disposed on the first passivation layer 190. The second semiconductor package 200 may include a wiring substrate 210, a plurality of second semiconductor chips 220 disposed on the wiring substrate 210, a second encapsulant 230 sealing the second semiconductor chip 220, and an upper connection terminal 265 in a lower portion of the wiring substrate 210.

In the case of the POP structure, as semiconductor chips are vertically stacked, heating becomes significant. Thus, there may be a problem in which a performance of a semiconductor chip is degraded. In detail, in the case of a Systerm on Chip (SoC) such as an application processor (AP), heat is generated locally in a position in which computation inside a semiconductor chip is performed. In this regard, a heat dissipation member disposed near such a heat generation position may be effective for heat dissipation. In the case of the semiconductor package 10A according to an example embodiment, a first semiconductor package 100, a fan-out semiconductor package, is introduced to mount a main semiconductor chip 120 such as an AP chip and to mount a semiconductor chip 220 such as a memory chip on an upper portion, while the thermoelectric device 150 is disposed on the inactive surface of the first semiconductor chip 120, so heat dissipation characteristics may be secured. Moreover, the thermoelectric device 150 is disposed in the through-hole 110H of the frame 110, thereby securing heat dissipation characteristics of a package without a change in a size such as an increase in a thickness of the package.

The thermoelectric device 150 may include heat conductive layers 151 forming an upper surface and a lower surface, semiconductor layers 155 disposed between the heat conductive layers 151 and having N-type and P-type conductivity, an electrode layer 152 disposed to connect a pair of semiconductor layers 155, and an insulating layer 153 filling a space between the semiconductor layers 155. In the thermoelectric device 150, at least a pair of N-type and P-type semiconductor layers 155, capable of performing a cooling action due to a Peltier effect, may be arranged alternately while forming a single thermoelectric couple. The Peltier effect refers to a phenomenon in which heat generation or heat absorption, different from joule heat, occurs, when a current is applied across different solids or semiconductors.

As illustrated in FIG. 10, the N-type and P-type semiconductor layers 155 may be alternately arranged, or arranged in a grid form, or arranged in a row. An electrical signal may be applied to the semiconductor layer 155 through the electrode layer 152, and a direction of a phenomenon of heat generation and heat absorption may be controlled according to polarity of the applied voltage or a direction of the current. For example, in FIG. 9, when a positive voltage is applied to an upper end of an N-type semiconductor layer 155 in a left side and a negative voltage is applied to an upper end of a P-type semiconductor layer 155 in aright side, electrons of the N-type semiconductor layer 155 may move toward an anode, and holes of the P-type semiconductor layer 155 may move toward a cathode. In other words, the electrons and the holes move from a bottom to a top, and heat moves from the bottom to the top depending on the flow of the electrons and holes. Here, a heat absorption phenomenon occurs in the bottom, an interface with the first semiconductor chip 120, and a heat generation phenomenon occurs in the top. Thus, the heat, generated from the first semiconductor chip 120, may be dissipated upwardly. The heat, dissipated upwardly, may be easily dissipated through a heat dissipation structure, disposed on the top, such as a heatpipe inside a set, or the like. In detail, the electrode layer 152 may receive an electrical signal through the second connection structure 170, so an additional space for the thermoelectric device 150 is not required. Moreover, even when the thermoelectric device 150 is disposed, a structure of a package and a size of a package may be maintained.

In the case of the semiconductor package 10A, in detail, a relatively large amount of heat is generated from the first semiconductor chip 120, such as an AP chip, and the heat, generated from the first semiconductor chip 120, may be actively emitted through the thermoelectric device 150. For example, when a central processing unit (CPU) or a graphics processing unit (GPU) in an application processor (AP) performs high-performance computing, a relatively large amount of heat is generated through such an operation. In this case, the thermoelectric device 150 is simultaneously operated. Thus, the heat, generated by the AP, is actively dissipated upwardly of a package in a short period of time, so performance degradation due to an increase in a temperature of the AP may be prevented. Moreover, in addition to the operation timing of the thermoelectric device 150, the operation time and the like may be controlled. Thus, heat dissipation may be efficiently performed as compared with a heat dissipation layer in the form depending on the material properties.

The respective components included in the fan-out semiconductor package 10A according to the example embodiment will hereinafter be described in more detail.

The frame 110 may improve rigidity of the first semiconductor package 100 depending on certain materials, and serve to secure uniformity of a thickness of the first encapsulant 130. Moreover, due to the frame 110, the fan-out semiconductor package 10A according to an example embodiment may be used as a portion of a POP structure. The frame 110 may have a through-hole 110H. The first semiconductor chip 120 may be disposed in the through-hole 110H to be spaced apart from the frame 110 by a predetermined distance. Side surfaces of the first semiconductor chip 120 may be surrounded by the frame 110. However, such a form is only an example and may be variously modified to have other forms, and another function may be performed depending on such a form. The frame 110 may be omitted if necessary, but the case having the frame 110 may be more advantageous in securing the board level reliability as intended in the present disclosure.

The frame 110 includes a core insulating layer 111, wiring layers 112 disposed on both sides of the core insulating layer 111, and a core via 113 passing through the core insulating layer 111 and connecting the wiring layers 112 disposed thereabove and therebelow. Thus, the wiring layers 112, disposed on both sides of the core insulating layer 111, may be electrically connected to each other through a core via 113.

For example, an insulating material may be used as the material of the core insulating layer 111. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Such a frame 110 may serve as a supporting member.

The wiring layers 112 may serve to redistribute the connection pads 122 of the first semiconductor chip 120. A material for formation of the wiring layer 112 may be a conductive material such as copper (Cu), aluminum (Al), silver (Ag), tin (Sn), gold (Au), nickel (Ni), lead (Pb), titanium (Ti), or alloys thereof. The wiring layer 112 may perform various functions depending on a design of a corresponding layer. For example, the wiring layers may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layer may include via pads, wire pads, connection terminal pads, and the like.

The core via 113 may electrically connect the wiring layers 112, formed on different layers, to each other, resulting in an electrical path in the frame 110. A material for formation of the core via 113 may be a conductive material. The core via 113 is completely filled with the conductive material, or the conductive material is also formed along a wall of a via hole. The core via may have all of the shapes known in the related art, such as a tapered shape, a cylindrical shape, and the like.

The first semiconductor chip 120 may be an integrated circuit (IC) provided in an amount of several hundred to several million or more elements integrated in a single chip. The IC may be, for example, a processor chip such as a central processor (for example, a central processing unit (CPU)), a graphics processor (for example, a graphics processing unit (GPU)), a field programmable gate array (FPGA), a digital signal processor, a cryptographic processor, a microprocessor, a microcontroller, or the like, in detail, an application processor (AP). However, the present disclosure is not limited thereto, and the semiconductor chip may be a logic chip such as an analog-to-digital converter (ADC), an application-specific integrated circuit (ASIC), or the like, or a memory chip such as a volatile memory (for example, a dynamic random access memory (DRAM)), a non-volatile memory (for example, a read only memory (ROM)), a flash memory, or the like, but is not limited thereto Moreover, these chip related components are also combined.

In the first semiconductor chip 120, a side, on which connection pad 122 is disposed, is an active surface, and the opposite side is an inactive surface. The first semiconductor chip 120 may be formed on the basis of an active wafer. In this case, a base material of a body 121 of the first semiconductor chip 120 may be silicon (Si), germanium (Ge), gallium arsenide (GaAs), or the like. Various circuits may be formed on the body 121. The connection pads 122 may electrically connect the first semiconductor chip 120 to other components. A material of each of the connection pads 122 may be a conductive material such as aluminum (Al), or the like. A passivation layer 123 exposing the connection pads 122 may be formed on the body 121, and may be an oxide layer, a nitride layer, or the like, or a double layer of an oxide layer and a nitride layer.

The adhesive layer 125 may allow the thermoelectric device 150 to be attached to the inactive surface of the first semiconductor chip 120. The adhesive layer 125 may be, for example, a tape such as a die attach film (DAF), but a material of the adhesive layer 125 is not particularly limited. The adhesive layer 125 may include an epoxy component or may include a heat transfer material, by way of example, but an embodiment is not limited thereto.

The thermoelectric device 150 is disposed on the inactive surface of the first semiconductor chip 120, and may be disposed in the through-hole 110H of the frame 110 together with the first semiconductor chip 120. The thermoelectric device 150 may be disposed to overlap the first semiconductor chip 120 on a plan view perpendicular to a stacking direction, and may have a size the same as that of the first semiconductor chip 120 in particular. The thermoelectric device 150 may have a thickness, the same as or greater than a thickness of the first semiconductor chip 120, but is not limited thereto. When the thermoelectric device 150 is formed to be relatively thick so as to use the most of a space in the through-hole 111H, an upper surface of the thermoelectric device 150 may be located at a level higher than that of an upper surface of the frame 110, in detail, an upper surface of the core insulating layer 111. In this case, the heat, emitted through the thermoelectric device 150, is able to be further easily emitted upwardly. The thermoelectric device 150 may be attached to the first semiconductor chip 120 by the adhesive layer 125.

The heat conductive layer 151 is a layer forming upper and lower surfaces of the thermoelectric device 150, and may be formed of a thermally conductive insulating material. The heat conductive layer 151 may be formed of, for example, polyimide, silicon boron nitride, aluminum oxide ceramics, or the like. However, the heat conductive layer 151 is not a necessary configuration, and may be omitted according to example embodiments. In this case, the semiconductor layer 155 may be directly disposed on the first semiconductor chip 120.

The semiconductor layer 155 is configured to further include N-type and P-type impurities in a medium of a semiconductor material such as silicon or silicon-germanium. Alternatively, the semiconductor layer 155 may include a Bi₂Te₃-based or PbTe-based material, having excellent resistance at high temperature. The N-type impurities may include at least one among nitrogen (N), phosphorus (P), arsenic (As), antimony (Sb), bismuth (Bi), sulfur (S), selenium (Se), tellurium (Te), and polonium (Po). Moreover, the P-type impurities may include at least one among boron (B), aluminum (Al), gallium (Ga), indium (In), thallium (Tl), zinc (Zn), cadmium (Cd), and mercury (Hg). The number of semiconductor layers 155, included in the thermoelectric device 150, and a size of each of the semiconductor layers 155 may be varied in various embodiments.

The electrode layer 152 electrically connects the semiconductor layers 155 with different conductivity types in series. The electrode layer 152 may include, for example, aluminum (Al), an aluminum alloy, copper (Cu), a copper alloy, nickel (Ni), a nickel alloy, or combinations thereof. The electrode layer 152 may have at least two terminal portions 152C, protruding outwardly, in an upper portion of the thermoelectric device 150. Through the two terminal portions 152C, power may be applied to the thermoelectric device 150 from the second connection structure 170. In FIG. 9, a single terminal portion 152C, located in an upper right side of the thermoelectric device 150, is illustrated, and another terminal portion may be further disposed in a region not illustrated. The electrode layer 152 extends horizontally to an outside of the thermoelectric device 150 through the terminal portion 152C and directly physically connected to the upper redistribution layer 172 of the second connection structure 170, and may receive an electrical signal from the upper redistribution layer 172. The terminal portion 152C extends to the frame 110 and connected to the upper redistribution layer 172, but is not limited thereto. Moreover, according to example embodiments, the terminal portion 152C does not extend horizontally to the frame 110, and connected to the upper redistribution layer 172 while having a bent portion or a curved form.

The insulating layer 153 may include an insulating material such as silicon oxide or silicon nitride while filling a space between the semiconductor layers 155. However, according to example embodiments, the insulating layer 153 may be omitted. In this case, an air gap may be provided between the semiconductor layers 155.

The first encapsulant 130 may protect the frame 110, the first semiconductor chip 120, and the like. An encapsulation form of the first encapsulant 131 is not particularly limited, but may be a form in which the first encapsulant 131 surrounds at least a portion of the first semiconductor chip 120. In this case, the first encapsulant 130 may cover at least portions of the frame 110 and an inactive surface of the first semiconductor chip 120, and fill at least a portion of a space between a wall surface of the through-hole 110H and a side surface of the first semiconductor chip 120. Meanwhile, the first encapsulant 130 may fill the through-hole 110H to thus serve as an adhesive for fixing the first semiconductor chip 120 and reduce buckling depending on certain materials. A material of the first encapsulant 130 is not particularly limited. For example, an insulating material may be used as the material of the first encapsulant 130. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a photo imageable dielectric (PID) resin may also be used.

The first connection structure 140 may redistribute the connection pads 122 of the first semiconductor chip 120. Several tens to several hundreds of connection pads 122 of the first semiconductor chip 120 having various functions may be redistributed by the first connection structure 140, and may be physically or electrically externally connected through the electrical connection metal 165 depending on functions. The first connection structure 140 may include a first insulating layer 141a disposed on the frame 110 and the active surface of the first semiconductor chip 120, a first redistribution layer 142a disposed on the first insulating layer 141a, a first via 143a connecting the first redistribution layer 142a to the connection pad 122 of the first semiconductor chip 120, a second insulating layer 141b disposed on the first insulating layer 141a, a second redistribution layer 142b disposed on the second insulating layer 141b, a second via 143b connecting the first and second redistribution layers 142a, 142b, and 142c, while passing through the second insulating layer 141b, a third insulating layer 141c disposed on the second insulating layer 141b, a third redistribution layer 142c disposed on the third insulating layer 141c, and a third via 143c connecting the second and third redistribution layers 142b and 142c while passing through the third insulating layer 141c. The first to third redistribution layers 142a, 142b, and 142c may be electrically connected to the connection pad 122 of the first semiconductor chip 120.

A material of each of the insulating layers 141a, 141b, and 141c may be an insulating material. In this case, a photosensitive insulating material such as a PID resin may also be used as the insulating material. That is, each of the insulating layers 141a, 141b, and 141c may be a photosensitive insulating layer. When the insulating layers 141a, 141b, and 141c have photosensitive properties, the insulating layers 141a, 141b, and 141c may be formed to have a smaller thickness, and a fine pitch of each of the vias 143a, 143b, and 143c may be achieved more easily. Each of the insulating layers 141a, 141b, and 141c may be a photosensitive insulating layer including an insulating resin and an inorganic filler. When the insulating layers 141a, 141b, and 141c are multiple layers, materials of the insulating layers 141a, 141b, and 141c may be the same as each other, and may also be different from each other, if necessary. When the insulating layers 141a, 141b, and 141c are multiple layers, the insulating layers 141a, 141b, and 141c may be integrated with each other depending on processes, so that a boundary therebetween may not be readily apparent. The number of insulating layers, greater than those illustrated in the drawings, may be provided.

The redistribution layers 141a, 141b, and 141c may substantially serve to redistribute the connection pads 122, and a formation material thereof may be a conductive material such as copper (Cu), aluminum (Al), silver (Ag), tin (Sn), gold (Au), nickel (Ni), lead (Pb), titanium (Ti), or alloys thereof. For example, a seed metal layer and a plating metal layer, forming the redistribution layers 142a, 142b, and 142c, are formed of copper (Cu) or alloys thereof, and the bonding metal layers may be formed of titanium (Ti) or alloys thereof. Here, the second bonding metal layer is a selective configuration, and may be omitted according to example embodiments. The redistribution layers 142a, 142b, and 142c may perform various functions depending on designs of corresponding layers. For example, the redistribution layers may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. Moreover, the redistribution layers 142a, 142b, and 142c may include via pad patterns, electrical connection metal pad patterns, and the like.

The vias 143a, 143b, and 143c may electrically connect the redistribution layers 142a, 142b, and 142c, the connection pads 122, and the like, formed on different layers, to each other, resulting in an electrical path in the package 10A. A material for formation of each of the vias 143a, 143b, and 143c may be a conductive material such as copper (Cu), aluminum (Al), silver (Ag), tin (Sn), gold (Au), nickel (Ni), lead (Pb), titanium (Ti), or alloys thereof. For example, a seed metal layer and a plating metal layer, forming the vias 143a, 143b, and 143c, are formed of copper (Cu) or alloys thereof, and the bonding metal layers may be formed of titanium (Ti) or alloys thereof. Each of the vias 143a, 143b, and 143c may be completely filled with a conductive material, or the conductive material may be formed along a wall of a via. In addition, the via 143a, 143b, and 143c may have all shapes known in the related art, such as a tapered shape, a cylindrical shape, and the like.

The second connection structure 170 may include an upper redistribution layer 172 disposed on the first encapsulant 130, and an upper via 173 passing through the first encapsulant 130. The upper via 173 may connect the upper redistribution layer 172 to the core via 113 of the frame 110. A material for formation of the upper redistribution layer 172 and the upper via 173 may be a conductive material such as copper (Cu), aluminum (Al), silver (Ag), tin (Sn), gold (Au), nickel (Ni), lead (Pb), titanium (Ti), or alloys thereof. The upper redistribution layer 172 may perform various functions depending on a design of a corresponding layer. For example, the upper redistribution layer may include ground (GND) patterns, power (PWR) patterns, signal (S) patterns, and the like. The upper via 173 may have a tapered shape in an opposite direction to the vias 143a, 143b, and 143c of the first connection structure 140.

The first passivation layer 190 may protect the first connection structure 140 from external physical or chemical damage. The first passivation layer 190 may have an opening exposing at least a portion of the third redistribution layer 142c of the first connection structure 140. The number of openings, formed in the first passivation layer 190, may be several tens to several thousands. A material of the first passivation layer 190 is not particularly limited. For example, an insulating material may be used as the material of the first passivation layer 190. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used. In a manner similar to the first passivation layer 190, a second passivation layer 195 may be formed on the second connection structure 170.

The underbump metal layer 160 may improve connection reliability of the electrical connection metal 165 to improve board level reliability of the semiconductor package 10A. The underbump metal layer 160 may be connected to the third redistribution layer 142c of the first connection structure 140, exposed through the openings of the first passivation layer 190. The underbump metal layer 160 may be formed in the openings of the first passivation layer 190 by any known metallization method using any known conductive material such as a metal, but is not limited thereto.

The electrical connection metal 165 may physically or electrically externally connect the fan-out semiconductor package 10A. For example, the fan-out semiconductor package 10A may be mounted on the mainboard of the electronic device through the electrical connection metal 165. The electrical connection metal 165 may be formed of a conductive material, for example, a solder or the like. However, this is only an example, and a material of each of the electrical connection metal 165 is not particularly limited thereto. Each of the electrical connection metals 165 may be a land, a ball, a pin, or the like. The electrical connection metals 165 may be formed as a multilayer or single layer structure. When the electrical connection metal includes the plurality of layers, the electrical connection metal includes a copper pillar and a solder. When the electrical connection metal includes the single layer, the electrical connection metal includes a tin-silver solder or copper. However, an embodiment is not limited thereto.

The number, an interval, a disposition form, and the like, of electrical connection metal 165 are not particularly limited, but may be sufficiently modified depending on design particulars by those skilled in the art. For example, the electrical connection metals 165 may be provided in an amount of several tens to several thousands, or may be provided in an amount of several tens to several thousands or more or several tens to several thousands or less. When the electrical connection metals 165 are solder balls, the electrical connection metals 165 may cover side surfaces of the underbump metal layer 160 extending onto one surface of the first passivation layer 190, and connection reliability may be more improved.

At least one of the electrical connection metals 165 may be disposed in a fan-out region of the first semiconductor chip 120. The fan-out package may have excellent reliability as compared to a fan-in package, may allow a plurality of input/output (I/O) terminals to be implemented, and may facilitate a 3D interconnection. In addition, as compared to a ball grid array (BGA) package, a land grid array (LGA) package, or the like, the fan-out package may be manufactured to have a small thickness, and may have price competitiveness.

The passive component 180 may be disposed on a lower surface of the first passivation layer 190, and may be disposed between the electrical connection metals 165. The passive component 180 may be electrically connected to a third redistribution layer 142c. The passive component 180 may include SMT components including, for example, inductors, capacitors, and the like.

Meanwhile, although not illustrated in the drawings, a metal thin film may be formed on the wall surface of the through-hole 110H for the purpose of radiating heat and/or shielding electromagnetic waves, if necessary. Moreover, a plurality of semiconductor chips, performing functions that are the same as or different from each other, may be disposed in the through-hole 110H, if necessary. In addition, a separate passive component such as an inductor, a capacitor, or the like, may be disposed in the through-hole 110H, if necessary.

The wiring substrate 210 may be a known printed circuit board (PCB) such as an interposer substrate. The wiring substrate 210 may include an insulating layer and a wiring layer, which is conductive and formed in the insulating layer. Passivation layers, or the like, may be formed on both sides of the wiring substrate 210. A structure and a form of the wiring substrate 210 may be varied in various example embodiments. Moreover, according to example embodiments, an interposer substrate may be further disposed between the wiring substrate 210 and the first semiconductor package 100.

The second semiconductor chip 220 may include a plurality of semiconductor chips 221, 222, 223, and 224, stacked in parallel. The second semiconductor chip 220 may be attached to the wiring substrate 210 or a second semiconductor chip 220 therebelow, by an adhesive member 225. The second semiconductor chip 220 may be electrically connected to the wiring layer 212 of the wiring substrate 210 by a wire 240 which is conductive and connected to the connection pad 221P. However, according to example embodiments, the second semiconductor chip 220 may be flip-chip bonded on the wiring substrate 210.

The second semiconductor chip 220 may also be an integrated circuit (IC) provided in an amount of several hundred to several million or more elements integrated in a single chip. The integrated circuit may be a memory chip such as a volatile memory (such as a DRAM), a non-volatile memory (such as a ROM), or the like, but is not limited thereto. In the second semiconductor chip 220, a side, on which a connection pad 221P is disposed, is an active surface, and the opposite side is an inactive surface. However, according to example embodiments, the second semiconductor chip 220 may be disposed in a face-down form. The second semiconductor chip 220 may be formed on the basis of an active wafer. In this case, a base material may be silicon (Si), germanium (Ge), gallium arsenide (GaAs), or the like. Various circuits may be formed in the second semiconductor chip 220. The connection pads 221P may electrically connect the second semiconductor chip 220 to other components. A material for formation of the connection pads 221P may be a conductive material such as aluminum (Al), or the like.

The adhesive member 225 may allow the inactive surface of the second semiconductor chip 220 to be easily attached to the second semiconductor chip 220 in a lower portion or an upper surface of the wiring substrate 210. The adhesive member 225 may be, for example, a tape such as a die attach film (DAF). A material of the adhesive member 225 is not particularly limited. The adhesive member 225 may include, for example, an epoxy component, but is not limited thereto. The second semiconductor chip 220 may be further stably mounted through the adhesive member 225, thereby improving reliability.

The second encapsulant 230 may protect the second semiconductor chip 220. An encapsulation form of the second encapsulant 230 is not particularly limited, but may be a form in which the second encapsulant 230 surrounds at least a portion of the second semiconductor chip 220. For example, the second encapsulant 230 may cover at least a portion of the active surface of the second semiconductor chip 220, or may cover at least a portion of a side surface. The second encapsulant 230 may include an insulating material. The insulating material may be photo imageable encapsulant (PIE), PID, or the like. However, it is not limited thereto, and the insulating material may be a material containing an inorganic filler and an insulating resin, for example, a thermosetting resin such as an epoxy resin, a thermoplastic resin such as a polyimid, or a resin in which a reinforcement such as an inorganic filler is contained in the thermosetting resin or the thermoplastic resin, in detail, an Ajinomoto build-up film (ABF), or the like. In addition, a known molding material, such as an epoxy molding compound (EMC), may also be used. As needed, a material in which the thermosetting resin or the thermoplastic resin is impregnated in a core material such as an inorganic filler and/or a glass fiber (or a glass cloth or a glass fabric), may be used.

The upper connection terminal 265 may electrically connect the wiring substrate 210 to the second connection structure 170. The upper connection terminal 265 may be interposed between the wiring layer 212 of the wiring substrate 210 and the upper redistribution layer 172 of the second connection structure 170. Each of the upper connection terminals 265 may be formed of a conductive material, for example, a solder or the like. However, this is only an example, and a material of each of the upper connection terminals 170 is not particularly limited thereto. The upper connection terminal 265 may be a land, a ball, a pin, or the like.

In an example embodiment, as an example of a semiconductor package, a POP structure in which a first semiconductor package 100 and a second semiconductor package 200 are stacked is described, but embodiments are not limited thereto. For example, the semiconductor package may only include the first semiconductor package 100, and another type of semiconductor device may be disposed on the first semiconductor package 100.

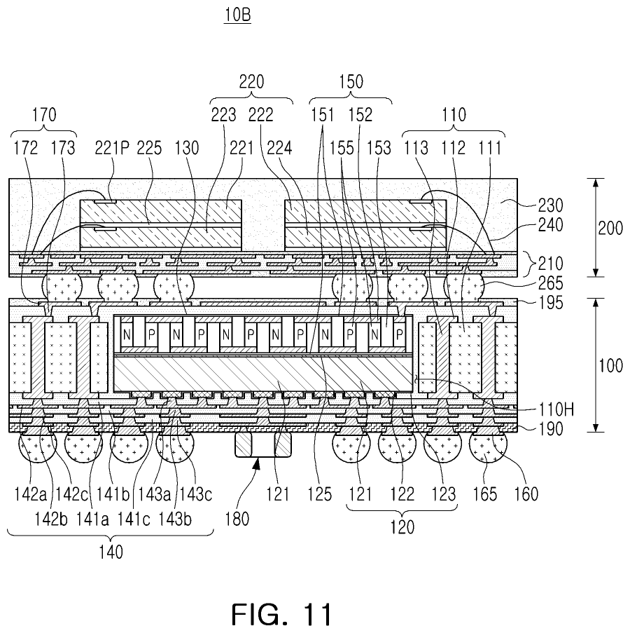

FIG. 11 is a schematic cross-sectional view illustrating another example of a semiconductor package.

Referring to FIG. 11, in a semiconductor package 10B according to another example embodiment, an electrode layer 152 of a thermoelectric device 150 is connected to an upper via 173 of a second connection structure 170, so the thermoelectric device 150 may receive a power signal from the second connection structure 170. In other words, the electrode layer 152 may be directly connected to the upper via 173, rather than the upper redistribution layer 172. The upper via 173 passes through the first encapsulant 130 and the upper heat conductive layer 151 of the thermoelectric device 150 to be connected to the electrode layer 152. In this case, while a process of the second connection structure 170 is used as it is, the upper via 173 and the electrode layer 152 are connected to each other, so a process may be significantly simplyfied. Moreover, in a region not illustrated, at least one N-type semiconductor layer 155 is also directly connected to the upper via 173 or the upper redistribution layer 172. According to example embodiments, it may also be possible that the thermoelectric device 150 may not include at least a heat conductive layer 151 in an upper portion. In this case, a connection process of the upper via 173 may be further facilitated. Other configurations and manufacturing processes are substantially the same as those described in the semiconductor package 10A according to the above-described example embodiment, and a detailed description thereof will be omitted.

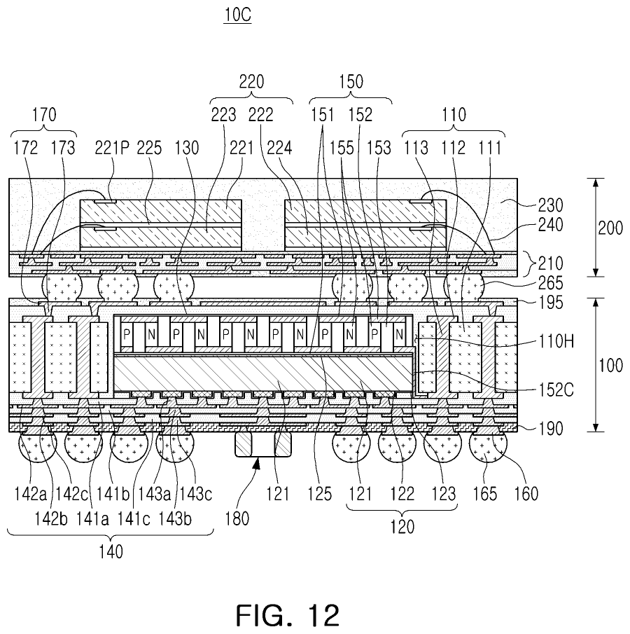

FIG. 12 is a schematic cross-sectional view illustrating another example of a semiconductor package.

Referring to FIG. 12, in a semiconductor package 10C according to another example embodiment, an electrode layer 152 of a thermoelectric device 150 may have a terminal portion 152C extending from a bottom of the thermoelectric device 150. The terminal portion 152C may extend along a side surface of the first semiconductor chip 120 from a bottom right side, and may be connected to the wiring layer 112 of the frame 110. Moreover, in a region not illustrated, a terminal portion 152C extends from the electrode layer 152, in contact with the P-type semiconductor layer 155, and may be connected to the wiring layer 112 of the frame 110. As described above, the electrode layer 152 of the thermoelectric device 150 is connected to the wiring layer 112 of the frame 110 in addition to the second connection structure 170, and may thus receive a power signal. Alternatively, according to an example embodiment, the electrode layer 152 of the thermoelectric device 150 extends along a side surface of the first semiconductor chip 120, and may be connected to the first redistribution layer 142a of the first connection structure 140 or the first via 143a, and may thus receive a power signal. The terminal portion 152C extends from the electrode layer 152 in a various manner. Moreover, an insulating layer may be interposed between a side surface of the first semiconductor chip 120 and the terminal portion 152C. Other configurations and manufacturing processes are substantially the same as those described in the semiconductor package 10A according to the above-described example embodiment, and a detailed description thereof will be omitted.

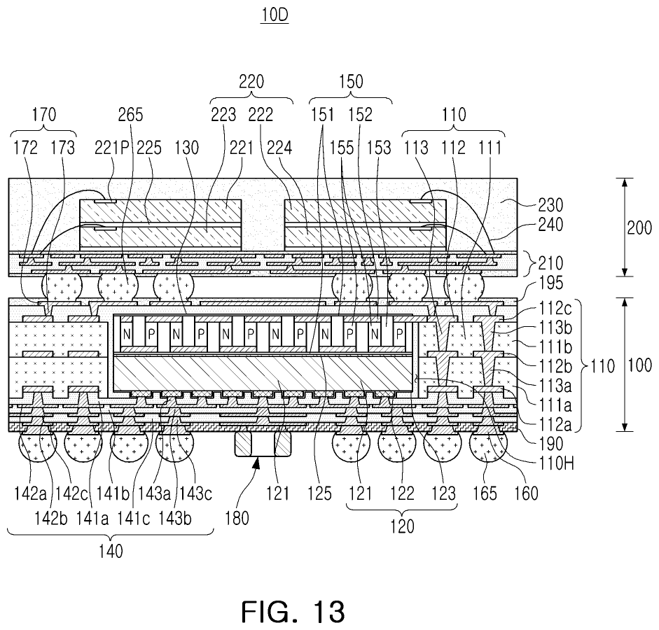

FIG. 13 is a schematic cross-sectional view illustrating another example of a semiconductor package.

Referring to FIG. 13, in a semiconductor package 10D according to another example, a frame 110 may include a first core insulating layer 111a in contact with a first connection structure 140, a first wiring layer 112a in contact with the first connection structure 140 and embedded in the first core insulating layer 111a, a second wiring layer 112b disposed on a side of the first core insulating layer 111a, opposite to a side, in which the first wiring layer 112a is embedded, a second core insulating layer 111b disposed on the first core insulating layer 111a and covering the second wiring layer 112b, and a third wiring layer 112c disposed on the second core insulating layer 111b. The first to third wiring layers 112a, 112b, and 112c are electrically connected to the connection pad 122. The first wiring layer 112a and the second wiring layer 112b, as well as the second wiring layer 112b and the third wiring layer 112c may be electrically connected to each other through the first via 113a and the second via 113b, passing through the first core insulating layer 111a and the second core insulating layer 111b, respectively.

The first wiring layer 112a may be recessed inwardly of the first core insulating layer 111a. As described above, when the first wiring layer 112a is recessed inwardly of the first core insulating layer 111a and a step is provided between a lower surface of the first core insulating layer 111a and a lower surface of the first wiring layer 112a, the first wiring layer 112a may be prevented from being contaminated by bleeding of a formation material of the first encapsulant 130. A thickness of each of the wiring layers 112a, 112b, and 112c of the frame 110 may be greater than that of each of the redistribution layers 142a, 142b, and 142c of the first connection structure 140.

A material of each of the core insulating layers 111a and 111b is not particularly limited. For example, an insulating material may be used as the material of each of the core insulating layers. In this case, the insulating material may be a thermosetting resin such as an epoxy resin, a thermoplastic resin such as a polyimid resin, or a resin in which the thermosetting resin or the thermoplastic resin is mixed with an inorganic filler, for example, an Ajinomoto build-up film (ABF), or the like. Alternatively, a PID resin may also be used.

When a hole for the first via 113a is formed, some pads of the first wiring layer 112a may serve as a stopper. In this regard, it may be advantageous in a process in that the first via 113a has a tapered shape in which a width of an upper surface is greater than a width of a lower surface. In this case, the first via 113a may be integrated with a pad pattern of the second wiring layer 112b. When a hole for the second via 113b is formed, some pads of the second wiring layer 112b may serve as a stopper. In this regard, it may be advantageous in a process in that the second via 113b has a tapered shape in which a width of an upper surface is greater than a width of a lower surface. In this case, the second via 113b may be integrated with a pad pattern of the third wiring layer 112c.

Other configurations and manufacturing processes are substantially the same as those described in the semiconductor package 10A according to the above-described example embodiment, and a detailed description thereof will be omitted.

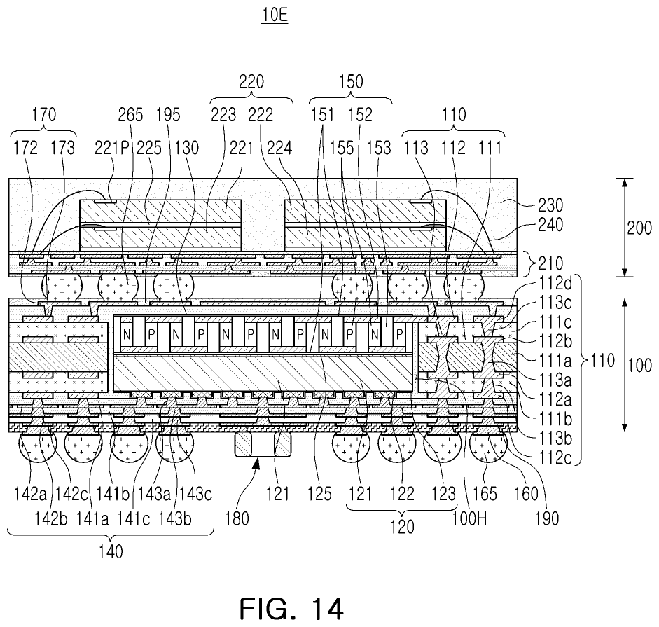

FIG. 14 is a schematic cross-sectional view illustrating another example of a semiconductor package.

Referring to FIG. 14, in a semiconductor package 10E according to another example, a frame 110 may include a first core insulating layer 111a, a first wiring layer 112a and a second wiring layer 112b disposed on both sides of the first core insulating layer 111a, respectively, a second core insulating layer 111b disposed on the first core insulating layer 111a and covering the first wiring layer 112a, a third redistribution layer 112c disposed on the second core insulating layer 111b, a third core insulating layer 111c disposed on the first core insulating layer 111a and covering the second wiring layer 112b, and a fourth wiring layer 112d disposed on the third core insulating layer 111c. The first to fourth wiring layers 112a, 112b, 112c, and 112d may be electrically connected to connection pads 122. Since the frame 110 may include a further large number of wiring layers 112a, 112b, 112c, and 112d, the first connection structure 140 may be further simplified. Therefore, a decrease in a yield depending on a defect occurring in a process of forming the first connection structure 140 may be suppressed. Meanwhile, the first to fourth wiring layers 112a, 112b, 112c, and 112d may be electrically connected to each other through first to third vias 113a, 113b, and 113c passing through the first to third core insulating layers 111a, 111b, and 111c, respectively.

The first core insulating layer 111a may have a thickness greater than those of the second core insulating layer 111b and the third core insulating layer 111c. The first core insulating layer 111a may be basically relatively thick in order to maintain rigidity, and the second core insulating layer 111b and the third core insulating layer 111c may be introduced in order to form a larger number of wiring layers 112c and 112d. The first core insulating layer 111a may include an insulating material different from those of the second core insulating layer 111b and the third core insulating layer 111c. For example, the first core insulating layer 111a may be, for example, prepreg including a core material, a filler, and an insulating resin, and the second core insulating layer 111b and the third core insulating layer 111c may be an ABF film or a PID film including a filler and an insulating resin. However, the materials of the first core insulating layer 111a and the second and third core insulating layers 111b and 111c are not limited thereto. Similarly, the first via 113a passing through the first core insulating layer 111a may have a diameter greater than those of the second and third vias 113b and 113c passing through the second and third core insulating layers 111b and 111c, respectively. In a similar manner, a thickness of each of the wiring layers 112a, 112b, 112c, and 112d of the frame 110 may be greater than that of each of the redistribution layers 142a, 142b, and 142c of the first connection structure 140.

Other configurations and manufacturing processes are substantially the same as those described in the semiconductor package 10A according to the above-described example embodiment, and a detailed description thereof will be omitted.

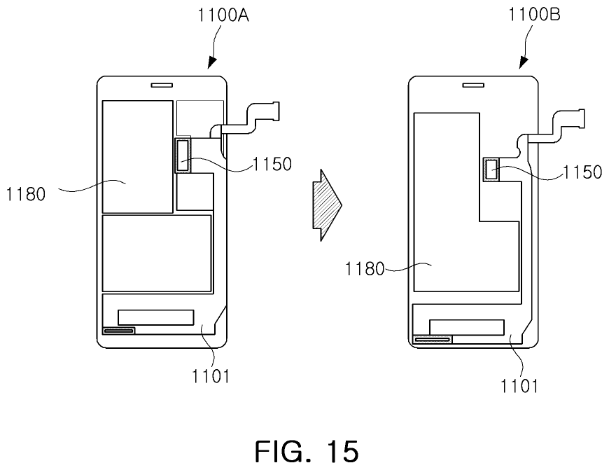

FIG. 15 is a schematic plan view illustrating an effect in a case in which the semiconductor package according to the disclosure is applied to an electronic device.

Referring to FIG. 15, recently, as a size of display for mobile devices 1100A and 1100B increases, the necessity of increasing battery capacity is increasing. Here, due to an increase in the battery capacity, an area occupied by the battery 1180 is increased. To this end, a reduction in a size of the printed circuit board 1101 such as a mainboard is required. Thus, due to a reduction in a mounting area of a component, an area occupied by a module 1150 including a power management integrated circuit (PMIC) and passive components is gradually decreased. In this case, when the semiconductor packages 10A, 10B, 10C, and 10D according to an example embodiment is applied to the module 1150, a size is able to be reduced. Thus, the area, which becomes smaller as described, above may be effectively used.

As set forth above, according to an example embodiment in the present disclosure, a semiconductor package with improved heat dissipation characteristics may be provided.

While example embodiments have been shown and described above, it will be apparent to those skilled in the art that modifications and variations could be made without departing from the scope of the present invention as defined by the appended claims.

What is claimed is:

1. A semiconductor package, comprising:
a frame having a through-hole;
a semiconductor chip disposed in the through-hole of the frame, and having an active surface on which a connection pad is disposed and an inactive surface opposite to the active surface;
a thermoelectric device disposed on the inactive surface of the semiconductor chip, in the through-hole of the frame, and including a semiconductor layer and an electrode layer connected to the semiconductor layer;
an encapsulant sealing at least portions of the semiconductor chip and the thermoelectric device; and
a first connection structure disposed on the active surface of the semiconductor chip, and including a first redistribution layer electrically connected to the connection pad of the semiconductor chip.

2. The semiconductor package of claim 1, further comprising:
a second connection structure disposed on the frame, and including a second redistribution layer electrically connected to the connection pad of the semiconductor chip and the electrode layer of the thermoelectric device.

3. The semiconductor package of claim 2, wherein the second connection structure further includes a via passing through a portion of the encapsulant and connected to the second redistribution layer, and
the via is connected to the electrode layer of the thermoelectric device.

4. The semiconductor package of claim 2, wherein the second redistribution layer is physically connected to the electrode layer of the thermoelectric device.

5. The semiconductor package of claim 4, wherein the electrode layer of the thermoelectric device includes a terminal portion protruding outwardly from the thermoelectric device, and
the terminal portion extends horizontally to an outside of the thermoelectric device and connected to the second redistribution layer.

6. The semiconductor package of claim 1, wherein the electrode layer of the thermoelectric device includes a terminal portion protruding outwardly from the thermoelectric device, and
the terminal portion extends along a side surface of the semiconductor chip and connected to a wiring layer of the frame.

7. The semiconductor package of claim 6, wherein an insulating layer is interposed between the side surface of the semiconductor chip and the terminal portion.

8. The semiconductor package of claim 1, wherein the electrode layer of the thermoelectric device includes a terminal portion protruding outwardly from the thermoelectric device, and
the terminal portion extends along a side surface of the semiconductor chip and connected to the first redistribution layer of the first connection structure.

9. The semiconductor package of claim 1, wherein the semiconductor layer of the thermoelectric device is disposed to overlap the semiconductor chip in a plan view perpendicular to a stacking direction.

10. The semiconductor package of claim 1, wherein an upper surface of the thermoelectric device is located at a level higher than a level of an upper surface of the frame in a stacking direction.

11. The semiconductor package of claim 1, wherein, in the thermoelectric device, the electrode layer is disposed in each of upper and lower surfaces of the semiconductor layer, and
the thermoelectric device further includes a heat conductive layer disposed in each of upper and lower surfaces of the electrode layer.

12. The semiconductor package of claim 1, wherein the semiconductor layer of the thermoelectric device is provided as a plurality of semiconductor layers spaced apart from each other and arranged in grid form.

13. The semiconductor package of claim 1, further comprising:
an adhesive layer disposed between the thermoelectric device and the semiconductor chip.

14. The semiconductor package of claim 1, further comprising:
a passive component attached to a lower surface of the first connection structure.

15. The semiconductor package of claim 1, wherein the frame includes a first core insulating layer, a first wiring layer in contact with the first connection structure and embedded in the first core insulating layer, a second wiring layer disposed on a side of the first core insulating layer opposite to a side in which the first wiring layer is embedded, a second core insulating layer disposed on the first core insulating layer and covering the second wiring layer, and a third wiring layer disposed on the second core insulating layer, and
the first to third wiring layers are electrically connected to the connection pad.

16. The semiconductor package of claim 1, wherein the frame includes a first core insulating layer, a first wiring layer and a second wiring layer disposed on both sides of the first core insulating layer, a second core insulating layer disposed on one surface of the first core insulating layer and covering the first wiring layer, and a third wiring layer disposed on the second core insulating layer, and
the first to third wiring layers are electrically connected to the connection pad.

17. The semiconductor package of claim 16, wherein the frame further includes a third core insulating layer disposed on another surface of the first core insulating layer and covering the second wiring layer, and a fourth wiring layer disposed on the third core insulating layer, and
The first to fourth wiring layers are electrically connected to the connection pad.

18. A semiconductor package, comprising:
a first semiconductor package including:
a frame having a through-hole, a first semiconductor chip disposed in the through-hole of the frame and having an active surface on which a connection pad is disposed and an inactive surface disposed opposite to the active surface;
a thermoelectric device disposed on the inactive surface of the first semiconductor chip in the through-hole of the frame;
a first encapsulant sealing at least a portion of the first semiconductor chip;
a first connection structure including a first redistribution layer disposed on the active surface of the first semiconductor chip and electrically connected to the connection pad of the first semiconductor chip; and
a second connection structure disposed on the frame and including a second redistribution layer electrically connected to the connection pad of the first semiconductor chip; and
a second semiconductor package disposed on the first semiconductor package, and including a wiring substrate electrically connected to the second connection structure through a connection terminal, at least one second semiconductor chip disposed on the wiring substrate, and a second encapsulant sealing at least a portion of the second semiconductor chip.

19. The semiconductor package of claim 18, wherein the thermoelectric device includes a semiconductor layer and an electrode layer connected to the semiconductor layer, and the second redistribution layer is electrically connected to the electrode layer.

20. The semiconductor package of claim 18, wherein the at least one second semiconductor chip is electrically connected to the wiring substrate by a wire.
